(19) United States
(12) Patent Application Publication
(10) Pub. No.: US 2016/0172200 A1
(43) Pub. Date: Jun. 16, 2016

(54) METHOD FOR FABRICATING NON-VOLATILE MEMORY DEVICE

(71) Applicant: UNITED MICROELECTRONICS CORP., Hsin-Chu City (TW)

(72) Inventors: WEICHANG LIU, Singapore (SG); ZHEN CHEN, Singapore (SG); Shen-De Wang, Hsinchu County (TW); Wei Ta, Singapore (SG); Yi-Shan Chiu, Taoyuan County (TW); Yuan-Hsiang Chang, Hsinchu City (TW); Chih-Chien Chang, Hsinchu City (TW)

(21) Appl. No.: 14/569,794

(22) Filed: Dec. 15, 2014

(51) Int. Cl. H01L 21/28

(52) U.S. Cl. CPC H01L 21/28282

(57) ABSTRACT

A method for fabricating non-volatile memory device is disclosed. The method includes the steps of: providing a substrate having a stack structure thereon; performing a first oxidation process to form a first oxide layer on the substrate and the stack structure; etching the first oxide layer for forming a first spacer adjacent to the stack structure; performing a second oxidation process to form a second oxide layer on the substrate; forming a dielectric layer on the first spacer and the second oxide layer; and etching the dielectric layer for forming a second spacer.

### BACKGROUND OF THE INVENTION

1. Field of the Invention

The invention relates to a method for fabricating non-volatile memory device.

2. Description of the Prior Art

Non-volatile memory devices are currently in widespread use in electronic components that require the retention of information when electrical power is terminated. Non-volatile memory devices include read-only-memory (ROM), programmable-read-only memory (PROM), erasable-programmable-read-only memory (EPROM), and electrically-erasable-programmable-read-only-memory (EEPROM) devices. EEPROM devices differ from other non-volatile memory devices in that they can be electrically programmed and erased electrically.

Product development efforts in memory device technology have focused on increasing the programming speed, lowering programming and reading voltages, increasing data retention time, reducing cell erasure times and reducing cell dimensions. Some of the flash memory arrays today utilize agate structure made of dual polysilicon layers (also refers to as the dual poly-Si gate). The polysilicon layer utilized in these gate structures often includes a dielectric material composed of an oxide-nitride-oxide (ONO) structure. When the device is operating, electrons are injected from the substrate into the bottom layer of the dual polysilicon layers for storing data. Since these dual gate arrays typically store only one single bit of data, they are inefficient for increasing the capacity of the memory. As a result, a flash memory made of silicon-oxide-nitride-oxide-silicon (SONOS) is derived. Preferably, a transistor from these memories is capable of storing two bits of data simultaneously, which not only reduces the size of the device but also increases the capacity of the memory significantly.

Despite the common utilization of these devices, current process for fabricating flash memory typically encounters issue such as loss of oxide adjacent to the ONO structure of the memory gate. Specifically, conventional oxide layer grown by high temperature oxidation (HTO) process is likely to suffer encroachment during numerous cleaning steps. Hence, how to improve the current fabrication for resolving the aforementioned issue has become an important task in this field.

### SUMMARY OF THE INVENTION

According to a preferred embodiment of the present invention, a method for fabricating non-volatile memory device is disclosed. The method includes the steps of: providing a substrate having a stack structure thereon; performing a first oxidation process to form a first oxide layer on the substrate and the stack structure; etching the first oxide layer for forming a first spacer adjacent to the stack structure; performing a second oxidation process to form a second oxide layer on the substrate; forming a dielectric layer on the first spacer and the second oxide layer; and etching the dielectric layer for forming a second spacer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7 illustrate a method for fabricating a flash memory device according to a preferred embodiment of the present invention.

### DETAILED DESCRIPTION

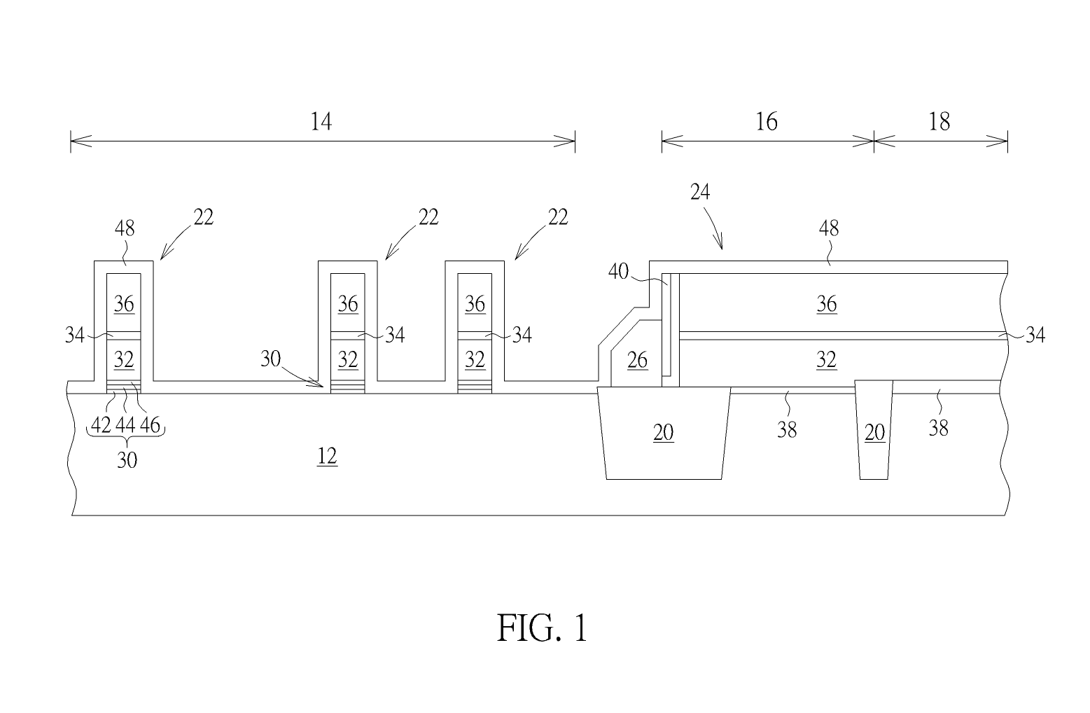

Referring to FIGS. 1-7, FIGS. 1-7 illustrate a method for fabricating a flash memory device according to a preferred embodiment of the present invention. As shown in FIG. 1, a substrate 12, such as a semiconductor substrate composed of gallium arsenide (GaAs), silicon on insulator (SOI) layer, epitaxial layer, silicon germanium layer, or other semiconductor materials is provided, in which a core region 14, a low-voltage (LV) device region 16, and a high-voltage (HV) device region 18 are defined on the substrate 12, and a plurality of shallow trench isolations (STIs) 20 are also formed in the substrate 12 for separating the regions 14, 16, and 18.

A plurality of stack structures 22 are then formed on the core region 14, a stack structure 24 is formed on the LV device region 16 and HV device region 18, and a pattern 26 is formed adjacent to the stack structure 24. Each of the stack structures 22 on the core region 18 is composed of an oxide-nitride-oxide (ONO) stack 30, a gate layer 32, a dielectric layer 34, and a cap layer 36. The stack structure 24 on the LV device region 16 and HV device region 18 is composed of a gate insulating layer 38, a gate layer 32, a dielectric layer 34, and a cap layer 36, and a dielectric stack 40 preferably composed of a silicon oxide layer and a silicon nitride layer is formed between the stack structure 24 and the pattern 26.

The ONO stack 30 preferably includes a tunnel oxide layer 42, a nitride layer 44, and a top oxide layer 46, in which the tunnel oxide 42 is preferably formed by an in-situ steam generation (ISSG) process, the nitride layer 44 is formed by a thermal process, and the top oxide layer 46 is formed by a ISSG process or a thermal oxidation process. The gate layer 32 and the pattern 26 are preferably composed of polysilicon, the dielectric layer 34 is composed of silicon oxide, and the cap layer 36 is composed of silicon nitride, but not limited thereto. As the formation of the stack structures 22 and 24 with ONO stack 30 and polysilicon gate layer is well known to those skilled in the art, the details of which are not explained herein for the sake of brevity.

After the stack structures 22 and 24 are fabricated, a first oxidation process is performed to form a first oxide layer 48 on the substrate 12, the stack structures 22 and 24 and the pattern 26. In this embodiment, the first oxidation process is preferably a high temperature oxidation (HTO) process, in which the temperature of the HTO process is between 700° C. to 950° C., and the thickness of the first oxide layer 48 is between 50 Angstroms to 200 Angstroms.

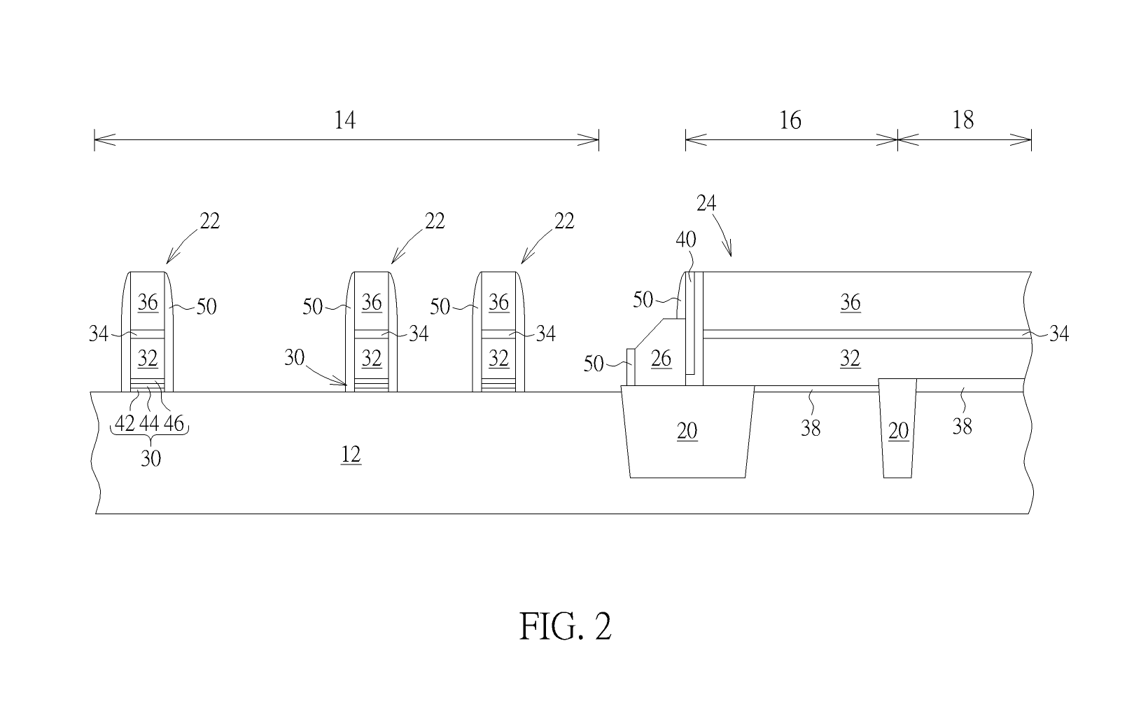

Next, as shown in FIG. 2, an etching process is conducted to remove part of the first oxide layer 48 for forming a first spacer 50 adjacent to the stack structures 22 and the pattern 26.

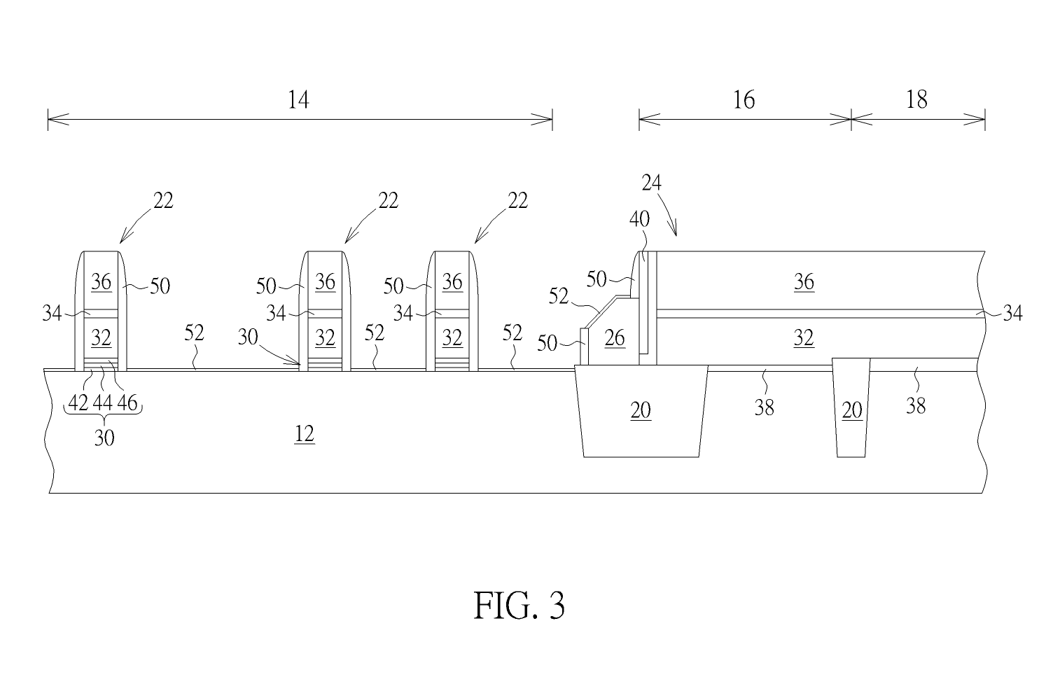

Next, as shown in FIG. 3, a second oxidation process is performed to form a second oxide layer 52 on the substrate 12, in which the second oxide layer 52 is preferably formed only on the exposed substrate 12 adjacent to the ONO stack 30 of the stack structures 22 and also on the pattern 26. In this embodiment, the second oxidation process is preferably a rapid thermal oxidation (RTO) process, in which the temperature of the RTO process is between 900° C. to 1100° C. and the thickness of the second oxide layer is between 10 Angstroms to 50 Angstroms, and preferably at 30 Angstroms.

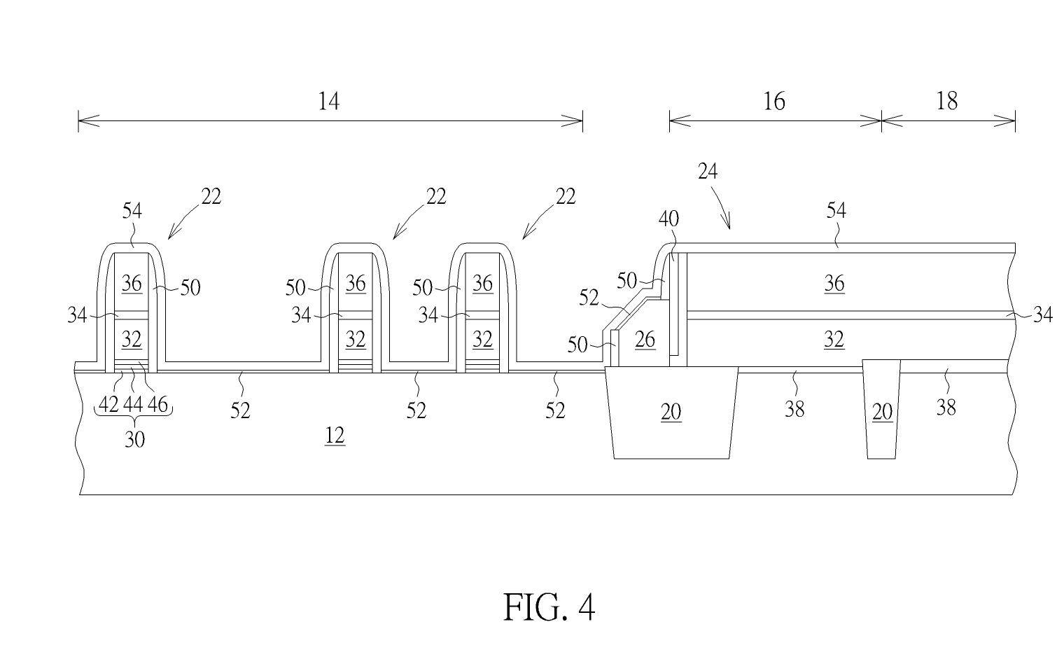

Next, as shown in FIG. 4, a dielectric layer 54 is deposited on the stack structures 22, the first spacer 50, the second oxide layer 52, and the pattern 26. Preferably, the dielectric layer 54 is composed of silicon nitride, and formed by a low temperature plasma-enhanced chemical vapor deposition (PECVD) process, but not limited thereto.

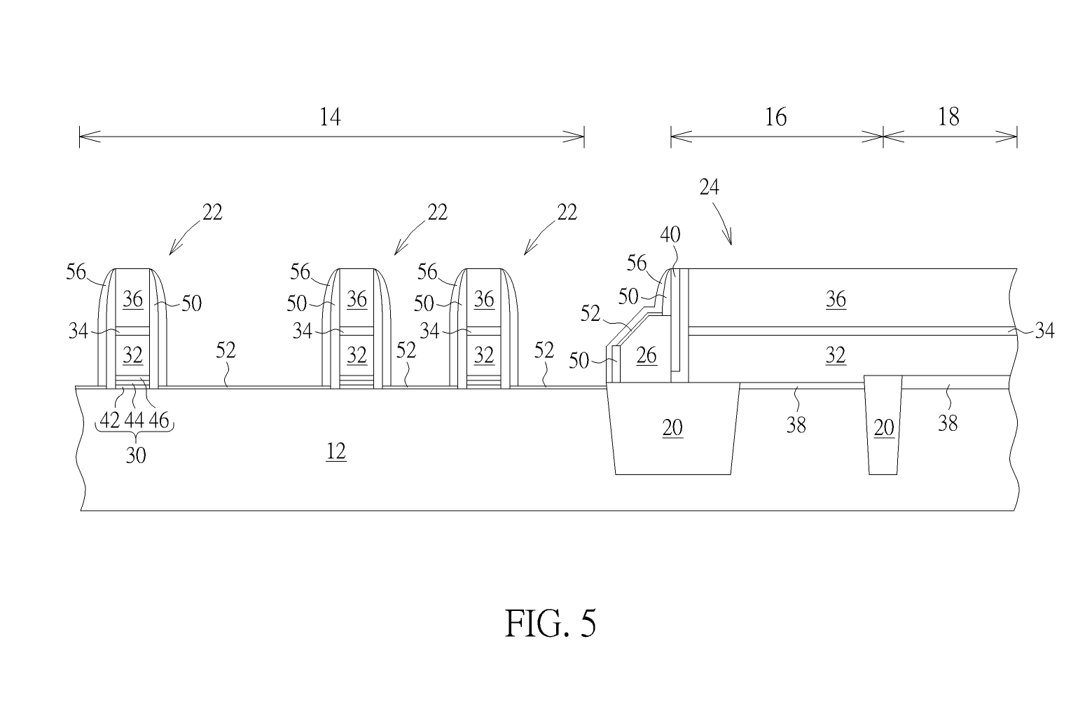

Next, as shown in FIG. 5, an etching process, preferably a dry etching process is conducted to remove part of the dielectric layer 54 for forming a second spacer 56 adjacent to the stack structures 22, in which the second spacer 56 preferably contacts the first spacer 50 and the second oxide layer 52 directly. In this embodiment, the second oxide layer 52 could not only be utilized as a buffer layer during the deposition of the dielectric layer 54, but also be used as a stop layer during the dry etching process of dielectric layer 54 for forming the second spacer 56.

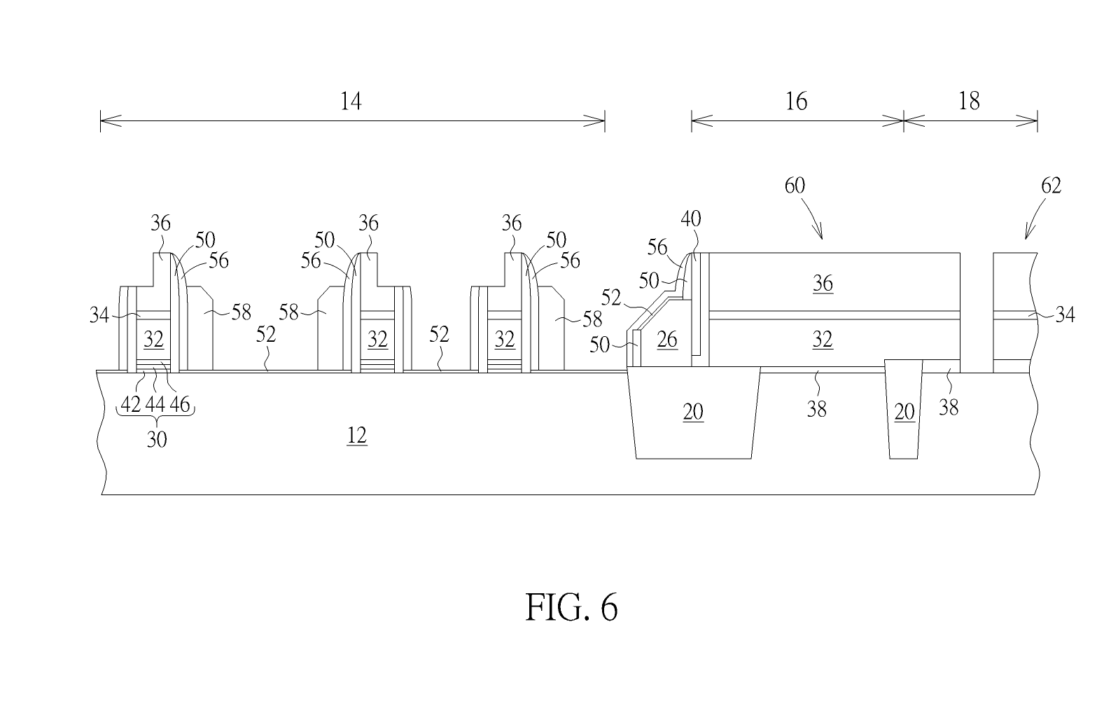

Next, as shown in FIG. 6, a select gate 58 is formed on the second oxide layer 52 of the core region 14 and adjacent to the second spacer 56, and a photo-etching process is conducted to pattern the stack structure 24 into a patterned stack 60 on the LV device region 16 and a high-voltage gate 62 on the HV device region 18. It should be noted that part of the cap layer 36, part of the first spacer 50, and part of the second spacer 56 are also removed during the patterning process.

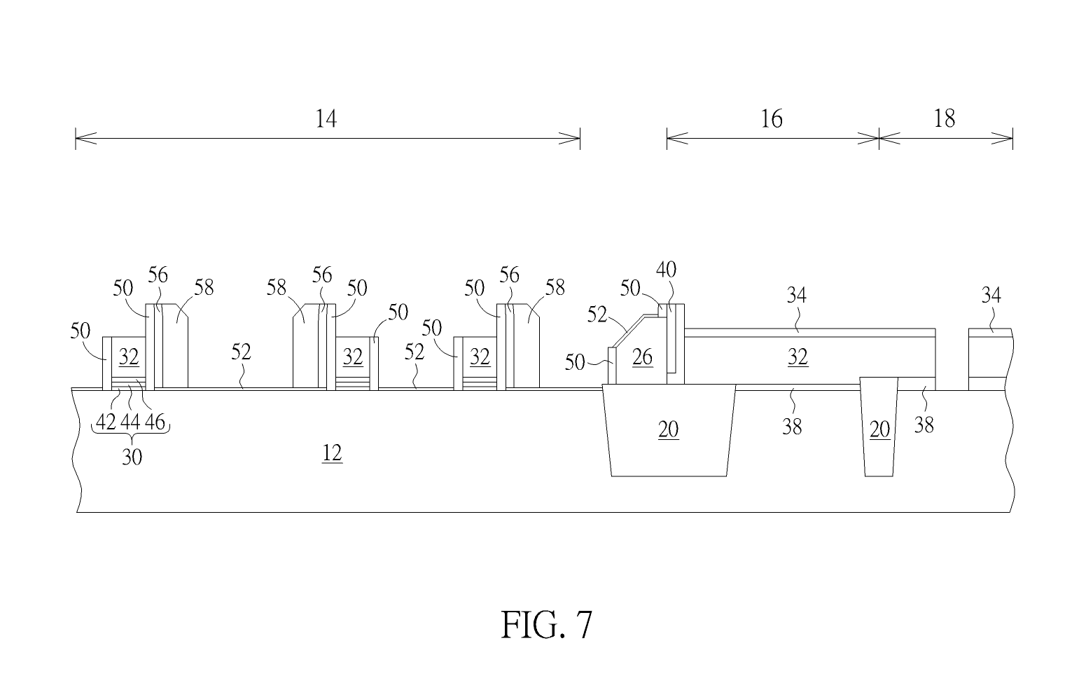

Next, as shown in FIG. 7, the cap layer 36 from the stack structures 22 and 24 along with part of the first spacer 50 and part of the second spacer 56 are removed. Next, a low-voltage gate could be defined on the LV device region 16 depending on the demand of the process, and elements such as additional spacers, source/drain regions, and silicides could be formed in the substrate 12 of the core region 14, low-voltage (LV) device region 16, and high-voltage (HV) device region 18, and as the formation of these elements are well known those skilled in the art, the details of which are not explained herein for the sake of brevity. This completes the fabrication of a non-volatile memory device according to a preferred embodiment of the present invention.

Overall, the present invention first conducts a HTO process to deposit a first oxide layer on the substrate and adjacent to the stack structure, removes part of the first oxide layer to forma first spacer, conducts a RTO process to form a second oxide layer on the substrate, and forms a second spacer adjacent to the first spacer and on the second oxide layer.

By using RTO process to form an oxide layer adjacent to the ONO stack of the core region, it would be desirable to boost up or increase the strength and durability of the oxide layer against etchant so that encroachment of the oxide layer could be prevented significantly. According to a preferred embodiment of the present invention, the second oxide layer grown by RTO process having an initial thickness of around 30 Angstroms has been found to maintain its thickness throughout the fabrication process.

Those skilled in the art will readily observe that numerous modifications and alterations of the device and method may be made while retaining the teachings of the invention. Accordingly, the above disclosure should be construed as limited only by the metes and bounds of the appended claims.

1. A method for fabricating non-volatile memory device, comprising:
providing a substrate having a stack structure thereon;
performing a first oxidation process to form a first oxide layer on the substrate and the stack structure;
etching the first oxide layer for forming a first spacer adjacent to the stack structure;
performing a second oxidation process to form a second oxide layer on the substrate;
forming a dielectric layer on the first spacer and the second oxide layer; and
etching the dielectric layer for forming a second spacer contacting the first spacer and the second oxide layer.

2. The method of claim 1, wherein the stack structure comprises an oxide-nitride-oxide (ONO) stack, a gate layer, and a cap layer.

3. The method of claim 2, wherein the ONO stack comprises a tunnel oxide layer, a nitride layer, and a top oxide layer.

4. The method of claim 2, wherein the gate layer comprises polysilicon.

5. The method of claim 2, wherein the cap layer comprises silicon nitride.

6. The method of claim 1, wherein the first oxidation process comprises a high temperature oxidation (HTO) process.

7. The method of claim 6, wherein the temperature of the HTO process is between 700° C. to 950° C.

8. The method of claim 6, wherein the thickness of the first oxide layer is between 50 Angstroms to 200 Angstroms.

9. The method of claim 1, wherein the second oxidation process comprises a rapid thermal oxidation (RTO) process.

10. The method of claim 9, wherein the temperature of the RTO process is between 900° C. to 1100° C.

11. The method of claim 9, wherein the thickness of the second oxide layer is between 10 Angstroms to 50 Angstroms.

12. The method of claim 1, wherein the dielectric layer comprises silicon nitride.

13. The method of claim 1, further comprising forming a select gate on the second oxide layer and adjacent to the second spacer.

14. The method of claim 1, wherein the second spacer contacts the first spacer and the second oxide layer directly.

15. The method of claim 1, wherein the second spacer is formed by a low temperature plasma-enhanced chemical vapor deposition (PECVD) process.
